(19) United States
(12) Patent Application Publication
(10) Pub. No.: US 2023/0377953 A1
(43) Pub. Date: Nov. 23, 2023

(54) SUBSTRATE PROCESSING METHOD AND SUBSTRATE PROCESSING APPARATUS

(71) Applicant: Tokyo Electron Limited, Minato-ku, Tokyo (JP)

(72) Inventor: Hiroki MURAKAMI, Nirasaki City, Yamanashi (JP)

(21) Appl. No.: 18/248,562

(22) PCT Filed: Oct. 1, 2021
(86) PCT No.: PCT/JP2021/036418

§ 371 Date: Apr. 11, 2023

(30) Foreign Application Priority Data
Oct. 15, 2020 (JP) 2020-173785

(51) Int. Cl. H01L 21/768; H01L 21/02; H01L 21/3105; H01L 21/311; C23C 16/40; C23C 16/34; C23C 16/52; H01J 37/32

(52) U.S. Cl. CPC H01L 21/7682; H01L 21/02164; H01L 21/0228; H01L 21/31055; H01L 21/31138; H01L 21/31116; H01L 21/76831; H01L 21/02115; H01L 21/0217; H01L 21/02211; C23C 16/402; C23C 16/345; C23C 16/52; H01J 37/32449; H01J 2237/3321; H01J 2237/3341

(57) ABSTRACT

A substrate processing method includes: preparing a substrate having a recess and a first film embedded in the recess; and removing the first film by etching while forming a second film so as to cover the recess from which the first film was removed by supplying a processing gas to the substrate, the processing gas including a gas contributing to film formation and a gas contributing to the etching.

### TECHNICAL FIELD

The present disclosure relates to a substrate processing method and a substrate processing apparatus.

### BACKGROUND

In recent years, semiconductor devices have become more and more highly integrated and miniaturized, and the narrowing of a pitch between wires causes an increased capacitance and significant signal delay. Therefore, in order to reduce a dielectric constant between wires, a technology for forming an air gap between the wires has been known. As a method of forming such an air gap, for example, Patent Document 1 discloses a technology for etching an interlayer insulation film using wires as a mask to form a recess serving as an air gap, and forming an interlayer insulation film as an upper layer on the recess under a poor step coverage condition. Further, Patent Document 2 discloses a technique in which, for a line-and-space structure, a film inside a space is removed by etching, and then a second insulation film, which is made of a material with poor wettability with respect to an insulation film around the space, is formed on the structure, and an air gap is formed between metal wires.

### PRIOR ART DOCUMENT

### Patent Document

Patent Document 1: Japanese Patent Laid-Open Publication No. 2009-295935
Patent Document 2: Japanese Patent Laid-Open Publication No. 2013-026347

The present disclosure provides a substrate processing method and a substrate processing apparatus which are capable of easily performing a processing requiring etching and film formation, such as air gap formation, with a small number of steps.

### SUMMARY

A substrate processing method according to one aspect of the present disclosure includes preparing a substrate having a recess and a first film embedded in the recess, and removing the first film by etching while forming a second film so as to cover the recess from which the first film was removed by supplying a processing gas to the substrate, the processing gas including a gas contributing to film formation and a gas contributing to etching.

According to the present disclosure, there are provided a substrate processing method and a substrate processing apparatus which are capable of easily performing a processing requiring etching and film formation, such as air gap formation, with a small number of steps.

### BRIEF DESCRIPTION OF DRAWINGS

FIG. 1 is a flowchart illustrating a substrate processing method according to a first embodiment.

FIG. 2 is a cross-sectional view illustrating a substrate to which the substrate processing method according to the first embodiment is applied.

FIG. 3 is a cross-sectional view illustrating a state of the substrate after performing the substrate processing method according to the first embodiment.

FIG. 4 is a cross-sectional view illustrating a state of the substrate after performing the substrate processing method according to the first embodiment.

FIG. 5 is a longitudinal sectional view illustrating an example of a substrate processing apparatus.

FIG. 6 is a horizontal sectional view illustrating the example of the substrate processing apparatus.

FIG. 7 is a horizontal sectional view illustrating an example of a substrate processing apparatus equipped with a plasma generation mechanism.

FIG. 8 is a cross-sectional view illustrating another example of a substrate processing apparatus.

FIGS. 9A and 9B are SEM photographs, respectively, illustrating a state where an air gap is formed by actually performing a substrate processing according to a first example as a specific example.

FIGS. 10A and 10B are SEM photographs, respectively, illustrating a state where an air gap is formed by actually performing a substrate processing according to a second example as a specific example.

FIG. 11 is a flowchart illustrating a pattern forming method including a substrate processing method according to a second embodiment.

FIG. 12 is a cross-sectional view illustrating a substrate to which the pattern forming method is applied.

FIG. 13 is a plan view illustrating the substrate to which the pattern forming method is applied.

FIG. 14 is a cross-sectional view illustrating a state of the substrate on which the substrate processing method according to the second embodiment is performed.

FIG. 15 is a cross-sectional view illustrating a state of the substrate after performing the substrate processing method according to the second embodiment.

FIG. 16 is a cross-sectional view illustrating a state where a pattern was formed on the substrate of FIG. 15.

### DETAILED DESCRIPTION

Hereinafter, embodiments will be described with reference to the accompanying drawings.

### First Embodiment

First, a first embodiment will be described.

### [Substrate Processing Method]

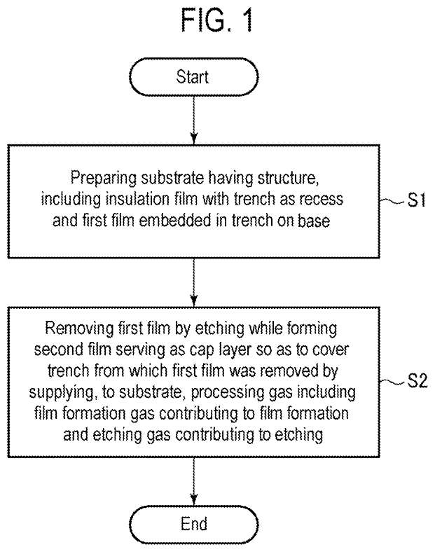

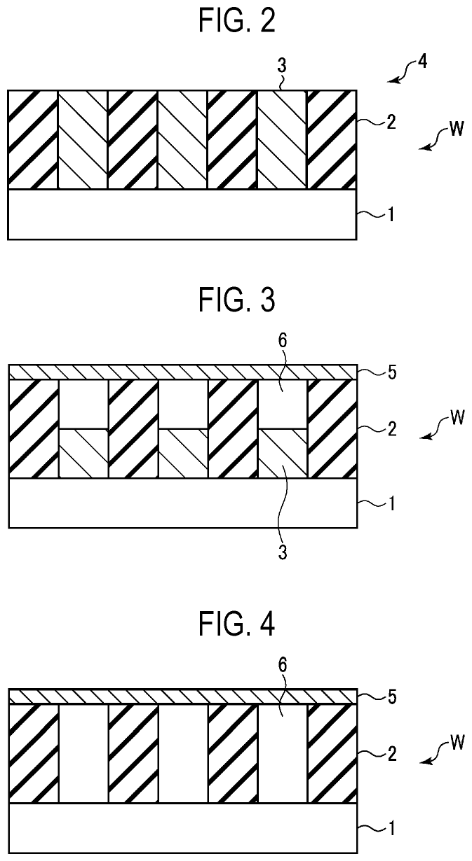

FIG. 1 is a flowchart illustrating a substrate processing method according to a first embodiment, FIG. 2 is a cross-sectional view illustrating a substrate to which the substrate processing method according to the first embodiment is applied, and FIGS. 3 and 4 are cross-sectional views, respectively, illustrating a state of the substrate after performing the substrate processing method according to the first embodiment.

In the substrate processing method according to the present embodiment, first, as illustrated in FIG. 2, a substrate W, which has a structure 4, including an insulation film 2 with a trench as a recess and a first film 3 embedded in the trench, on a base 1, is prepared (step S1).

Then, a processing gas including a film formation gas contributing to film formation and an etching gas contributing to etching is supplied to the substrate W, and as illustrated in FIGS. 3 and 4, while removing the first film 3 by etching, a second film 5 serving as a cap layer is formed so as to cover the trench from which the first film was removed (step S2).

The substrate W is not particularly limited, but a semiconductor wafer in which the base 1 includes a semiconductor base is exemplified. The insulation film 2 is, for example, an interlayer insulation film, and is exemplified by a SiO₂ film, SiN film, SiOC film, SiOCN film, SiCN film, SiBN film, and SiBCN film. The first film 3 is a film that is removed by etching with the etching gas, and a material thereof is appropriately selected depending on the combination with the used etching gas, as will be described later.

In step S2, the film formation of the second film 5 serving as the cap layer and the etching of the first film 3 may proceed simultaneously. Thus, the second film 5 is also formed on a portion where the first film 3 was removed by etching, so that an air gap 6 surrounded by the insulation film 2 and the second film 5 is formed.

In step S2, the processing gas may include an inert gas functioning as a carrier gas, a purge gas, and a diluent gas, in addition to the film formation gas and the etching gas. The film formation gas may be one that forms a film by thermal decomposition, or may be one that forms a film by reacting with a reactive gas. When using the reactive gas, the reactive gas may be used as the etching gas.

A chemical vapor deposition (CVD) method may be used as a film forming method of the second film 5 serving as the cap layer. When using the reactive gas, an atomic layer deposition (ALD) method in which the film formation gas and the reactive gas are alternately supplied may be used. Further, plasma may be used during film formation. A film thickness of the second film 5 may be 0.1 nm to 20 nm.

Examples of the etching gas may include a halogen-containing gas (for example, a Cl₂ gas, a BCl₃ gas, a F₂ gas, a HF gas, a HI gas, a HBr gas, a CH₃I gas, and a C₂H₅I gas), an oxidizing gas (for example, an O₂ gas, an O₃ gas), an O₂ plasma, a H₂O gas, and a H₂O₂ gas), a nitriding gas (H₂/NH₃ plasma, and a hydrazine compound), and the like.

When the etching gas is a halogen-containing gas such as a Cl₂ gas, silicon (Si), germanium (Ge), tungsten (W), boron (B), aluminum (Al), or the like may be used as the first film 3 to be removed by etching. These may react with halogen to form a substance with a high vapor pressure, and may be removed by volatilization.

Further, when the etching gas is an oxidizing gas such as an O₂ gas or an O₃ gas), ruthenium (Ru), carbon (C) (organic film), or the like may be used as the first film 3 to be removed by etching. These oxides have a high vapor pressure, and are vaporized and removed by oxidation.

When the etching gas is a nitriding gas such as H₂/NH₃ plasma, an organic film may be used as the first film 3 to be removed by etching. The organic film may be ashed by H₂/NH₃ plasma or the like.

The film formation gas is not particularly limited as long as it may form the second film 5 serving as the cap layer, but a carbon compound gas such as a hydrocarbon gas, or a silicon compound gas such as a silane-based gas, a chlorosilane-based gas or an aminosilane-based gas may be suitably used as the film formation gas.

When a carbon compound gas is used as the film formation gas, a C film (organic film) may be formed by thermally decomposing the carbon compound gas. The etching gas may be selected depending on the material of the first film 3, but may be a Cl₂ gas. The Cl₂ gas has an effect of lowering a film formation temperature of the C film. When the Cl₂ gas is used as the etching gas, Si, Ge, W, B, Al or the like may be used as the first film 3 as described above.

Further, when a silicon compound gas is used as the film formation gas, a SiO₂ film may be formed as the second film 5 by using, as the reactive gas, an oxidizing gas such as an O₂ gas or an O₃ gas). Further, a SiN film may be formed as the second film 5 by using a nitriding gas such as H₂/NH₃ plasma as the reactive gas. In this case, these reactive gases may be used as the etching gas. That is, when an oxidizing gas such as an O₂ gas or an O₃ gas) is used as the reactive gas, Ru, C or the like may be used as the first film 3, so that the oxidizing gas functions as the etching gas, and both the removal of the first film 3 by etching and the formation of the SiO₂ film, which is the second film 5, may proceed. Further, when H₂/NH₃ plasma is used as the reactive gas, an organic compound may be used as the first film 3, so that H₂/NH₃ plasma functions as the etching gas, and both the removal of the first film 3 by etching and the formation of the SiN film, which is the second film 5, may proceed.

In step S2, both the removal of the first film 3 by etching and the formation of the second film 5 serving as the cap layer proceed as described above, but it is possible to adjust a removal amount of the first film 3 and a thickness of the second film 5 by adjusting processing conditions. By adjusting the removal amount of the first film 3, it is also possible to remove the first film 3 halfway as illustrated in FIG. 3, or to completely remove the first film 3 as illustrated in FIG. 4. The processing conditions at this time may include a gas supply timing, a processing temperature, a gas flow rate, a gas ratio, and the like.

In step S2, the second film 5 serving as the cap layer may be formed so as to cover the trench by giving film formation superiority over etching. By making the ratio of the film formation gas higher than that of the etching gas, film formation may attain superiority. Further, etching may attain superiority by including a period in which only the film formation gas is supplied. For example, film formation may attain superiority by initially supplying the film formation gas to precede film formation, and then supplying the film formation gas and the etching gas.

In the related art, forming an air gap was cumbersome because, as described in Patent Documents 1 and 2, it is necessary to perform the formation of a trench by etching and the formation of a film on an upper surface of the trench in separate steps and a research is also needed to prevent the trench from being embedded during film formation.

On the other hand, in the present embodiment, the air gap 6 may be formed by forming the second film 5 serving as the cap layer while etching the first film 3, which makes it possible to easily form the air gap with a small number of steps.

Further, when the second film 5 serving as the cap layer is a C film, it may be removed relatively easily, which is useful because subsequent steps may be easily performed. For example, in a wire formation step, after forming an air gap, formation, lithography and the like of another film on the cap layer are performed, and then the cap layer may be easily penetrated, which may allow easy implementation of connection from a via to a lower layer wire by one effort. Furthermore, when a SiO₂ film or a SiN film is used as the second film 5 serving as the cap layer, it is useful when insulation properties are required.

Furthermore, the etching amount of the first film 3, the thickness of the second film 5, and the like may be adjusted depending on processing conditions. Further, various combinations of the materials of the first film 3 and the second film 5 and of the film formation gas and the etching gas (reactive gas) may be selected. For this reason, the degree of freedom of application is extremely high.

### [Example of Substrate Processing Apparatus]

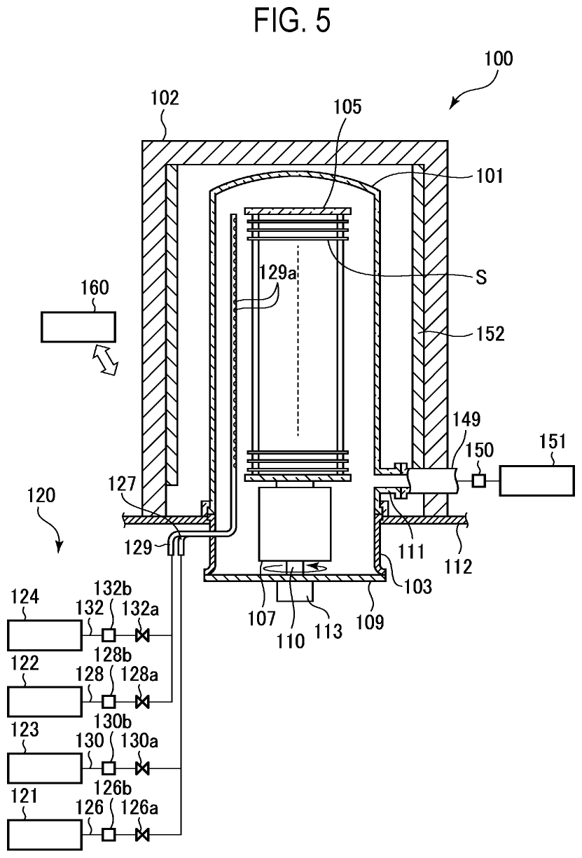

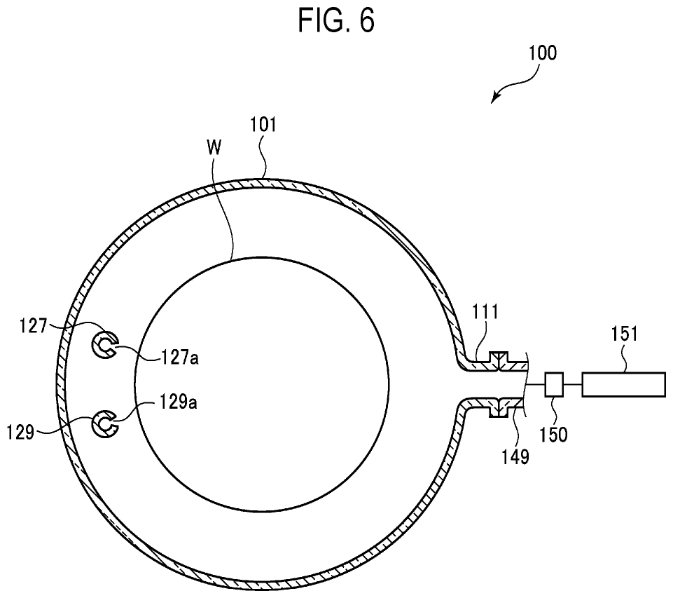

Next, an example of a substrate processing apparatus capable of performing the substrate processing method as described above will be described. FIG. 5 is a longitudinal sectional view illustrating an example of a substrate processing apparatus, and FIG. 6 is a horizontal sectional view thereof.

A substrate processing apparatus 100 of this example is configured as a batch-type vertical furnace, and includes a roofed processing container 101 configured as a reaction tube. The entire processing container 101 is made of, for example, quartz. A boat 105 made of quartz, on which, for example, 50 to 150 substrates W such as semiconductor wafers having the above-described structure of FIG. 2 are stacked in multiple stages, is arranged inside the processing container 101. A substantially cylindrical main body 102 having an open lower surface side is provided outside the processing container 101, and a heating mechanism 152 equipped with a heater is provided in the circumferential direction on an inner wall surface of the main body 102. The main body 102 is supported by a base plate 112.

A manifold 103, which is molded into, for example, a cylindrical shape using stainless steel, is connected to a lower end opening of the processing container 101 via a seal member (not illustrated) such as an O-ring.

The manifold 103 supports the processing container 101, and the boat 105 is inserted into the processing container 101 from below the manifold 103. The bottom of the manifold 103 is closed by a lid 109.

The boat 105 is placed on a heat insulation cylinder 107 made of quartz, and a rotary shaft 110 is installed in the heat insulation cylinder 107 to penetrate the lid 109. The rotary shaft 110 may be rotated by a rotation driving mechanism 113 such as a motor. Thus, the boat 105 may be rotated via the heat insulation cylinder 107 by the rotation driving mechanism 113. In addition, the heat insulation cylinder 107 may be fixed to the side of the lid 109 and the substrate W may be processed without rotating the boat 105.

The substrate processing apparatus 100 includes a gas supply mechanism 120. The gas supply mechanism 120 includes a first gas source 121, a second gas source 122, and inert gas sources 123 and 124. A pipe 126 is connected to the first gas source 121, and a gas dispersion nozzle 127 made of quartz is connected to the pipe 126. The gas dispersion nozzle 127 penetrates a sidewall of the manifold 103 and the processing container 101 and is bent upward inside the processing container 101 to vertically extend. A pipe 128 is connected to the second gas source 122, and a gas dispersion nozzle 129 made of quartz is connected to the pipe 128. The gas dispersion nozzle 129 penetrates the sidewall of the manifold 103 and the processing container 101 and is bent upward inside the processing container 101 to vertically extend. The inert gas source 123 is connected to a pipe 130, and in turn, the pipe 130 is connected to the pipe 126. The inert gas source 124 is connected to a pipe 132, and in turn, the pipe 132 is connected to the pipe 128.

The film formation gas is supplied from the first gas source 121, and the etching gas is supplied from the second gas source 122. When film formation requires a reactive gas, the reactive gas may be used as the etching gas and is supplied from the second gas source 122. An inert gas such as a N₂ gas or an Ar gas is supplied from the inert gas sources 123 and 124. The inert gas is used as a carrier gas, a purge gas, or a diluent gas.

The film formation gas is supplied from the first gas source 121 and the etching gas (or the reactive gas as the etching gas) is supplied from the second gas source 122, so that a film may be formed by CVD or ALD simultaneously with etching. In addition, the reactive gas may be used separately from the etching gas, and a plurality of gases may be used as the film formation gas, the etching gas, or the reactive gas. In these cases, the number of gas sources, pipes, and dispersion nozzles may be increased depending on the types of gases.

The pipe 126 is provided with an on-off valve 126a and a flow rate controller 126b such as a mass flow controller on the upstream side thereof. Further, the pipes 128, 130 and 132 are similarly provided with on-off valves 128a, 130a and 132a and flow rate controllers 128b, 130b and 132b, respectively.

A plurality of gas discharge holes 127a and 129a are formed in vertical portions of the gas dispersion nozzles 127 and 129 at predetermined intervals to correspond to each substrate W over a vertical length corresponding to a substrate support range of the boat 105 (only gas discharge holes 129a are illustrated in FIG. 5). Thus, the gas may be substantially uniformly discharged from each gas discharge hole toward the processing container 101 in the horizontal direction.

An exhaust port 111 is formed in a portion of the processing container 101 facing the arrangement positions of the gas dispersion nozzles 127 and 129. An exhaust pipe 149 for exhausting the processing container 101 is connected to the exhaust port 111. The exhaust pipe 149 is connected to an exhaust device 151, which includes a pressure control valve 150 for controlling an internal pressure of the processing container 101, a vacuum pump, and the like. The interior of the processing container 101 is exhausted by the exhaust device 151 through the exhaust pipe 149.

The processing container 101 and the substrate W provided therein are heated to a desired temperature by supplying power to the heating mechanism 152 inside the main body 102 described above.

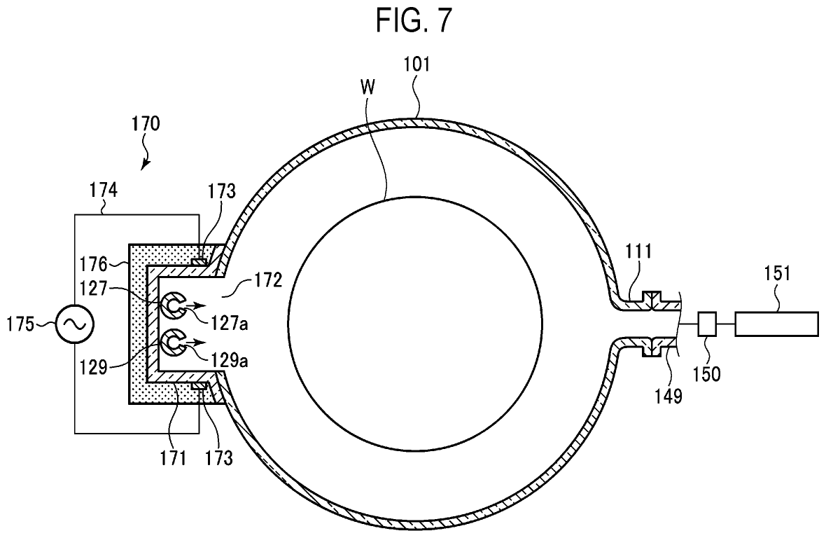

The gas to be supplied may be plasmarized during film formation. In that case, for example, a plasma generation mechanism 170 illustrated in FIG. 7 is provided. The plasma generation mechanism 170 includes a plasma partition wall 171 airtightly bonded to an outer wall of the processing container 101. The plasma partition wall 171 is made of, for example, quartz. The plasma partition wall 171 has a recessed cross section and covers an opening 172 formed in the sidewall of the processing container 101. The opening 172 is formed to be elongated in the vertical direction so as to cover all the substrates W supported in the boat 105 in the vertical direction. The gas dispersion nozzles 127 and 129 are arranged inside a plasma generation space defined by the plasma partition wall 171. In addition, when only one of the film formation gas and the etching gas is plasmarized, only the gas dispersion nozzle corresponding thereto may be arranged in the plasma generation space.

The plasma generation mechanism 170 further includes a pair of plasma electrodes 173 and a radio-frequency power supply 175. The pair of plasma electrodes 173 are arranged on both sidewall outer surfaces of the plasma partition wall 171 so as to face each other in the vertical direction. The radio-frequency power supply 175 is connected to each of the pair of plasma electrodes 173 via a power feed line 174, and supplies radio frequency power to the pair of plasma electrodes 173. The radio-frequency power supply 175 applies radio frequency power of, for example, 13.56 MHz. Thus, a radio frequency electric field is applied in the plasma generation space defined by the plasma partition wall 171, and the gas discharged from the gas dispersion nozzles 127 and/or 129 is plasmarized.

The outside of the plasma partition wall 171 is covered with an insulating protective cover 176 made of, for example, quartz. A coolant passage (not illustrated) is provided in an inner portion of the insulating protective cover 176. The pair of plasma electrodes 173 may be cooled down by flowing, for example, a cooled nitrogen gas.

The substrate processing apparatus 100 includes a controller 160. The controller 160 controls each component of the substrate processing apparatus 100 such as a valve, a flow rate controller, various driving mechanisms, and the heating mechanism 152. The controller 160 includes a main controller equipped with a CPU, an input device, an output device, a display device, and a storage device. A storage medium that stores a program, that is, a processing recipe for controlling a processing executed in the substrate processing apparatus 100, is set in the storage device. The main controller calls a predetermined processing recipe stored in the storage medium, and controls the substrate processing apparatus 100 to execute a predetermined processing based on the processing recipe.

In the substrate processing apparatus 100 configured as described above, the controller 160 performs a processing as follows based on the processing recipe stored in the storage medium.

First, in an ambient atmosphere, a plurality of, for example, 50 to 150 substrates W having the structure illustrated in FIG. 2 are loaded to the boat 105, and the boat 105 is inserted into the processing container 101 from below, so that the plurality of substrates W are accommodated in the processing container 101. Then, the internal space of the processing container 101 is closed by closing the lower end opening of the manifold 103 with the lid 109.

Subsequently, while the interior of the processing container 101 is exhausted by the exhaust device 151 to adjust the internal pressure of the processing container 101, the inert gas such as a N₂ gas is supplied, and a temperature of the substrate W is raised to a predetermined temperature by the heating mechanism 152.

Subsequently, while continuing to supply the inert gas, the film formation gas and the etching gas (or the reactive gas as the etching gas) are supplied toward the substrate W from the gas discharge holes 127a and 129a of the gas dispersion nozzles 127 and 129 at a predetermined timing. Thus, as illustrated in FIGS. 3 and 4, the second film 5 serving as the cap layer may be formed while etching the first film 3, which may result in the formation of the air gap 6.

After the above processing is completed, the interior of the processing container 101 is purged with the inert gas, and then, the interior of the processing container 101 is returned to the atmospheric pressure, and the boat 105 is unloaded downward.

### [Another Example of Substrate Processing Apparatus]

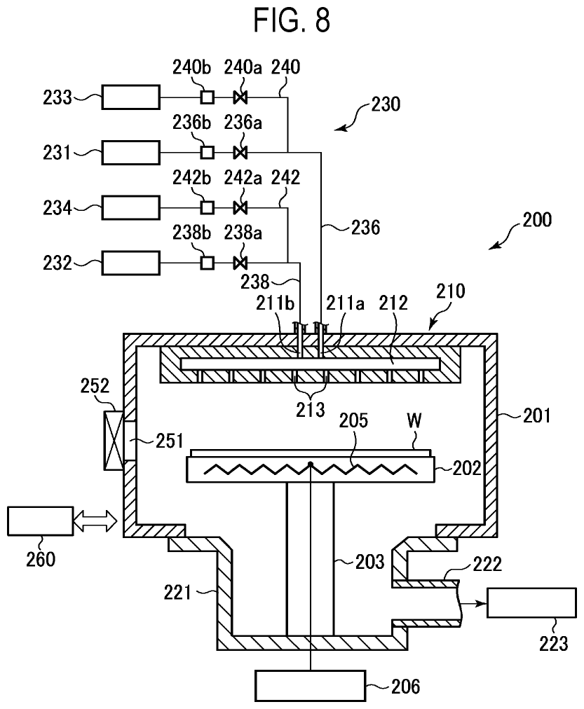

Next, another example of a substrate processing apparatus capable of performing the substrate processing method as described above will be described. FIG. 8 is a cross-sectional view illustrating another example of the substrate processing apparatus.

In the above example, a batch-type vertical furnace is illustrated as the substrate processing apparatus, but in this example, a single-wafer-type substrate processing apparatus is illustrated.

A substrate processing apparatus 200 of this example includes a substantially cylindrical processing container 201 configured in an airtight manner. A susceptor 202 serving as a stage for placing the substrate W thereon is arranged inside the processing container 201 and is supported by a cylindrical support member 203 provided at the center of a bottom wall of the processing container 201. A heater 205 is embedded in the susceptor 202. The heater 205 heats the substrate W to a predetermined temperature upon receiving power supplied from a heater power supply 206. In addition, the susceptor 202 is provided with a plurality of lifting pins (not illustrated) configured to move upward and downward with respect to a surface of the susceptor 202 so as to support and lift the substrate W.

A shower head 210 for introducing a processing gas into the processing container 201 in the form of a shower is provided on a ceiling wall of the processing container 201 so as to face the susceptor 202. The shower head 210 is for discharging a gas supplied from a gas supply mechanism 230, which will be described later, into the processing container 201, and includes a first gas inlet 211a and a second gas inlet 211b for introducing the gas at an upper portion thereof. Further, a gas diffusion space 212 is formed inside the shower head 210. A large number of gas discharge holes 213 communicating with the gas diffusion space 212 are formed in a bottom surface of the shower head 210.

An exhaust chamber 221 is provided on a bottom wall of the processing container 201 to protrude downward. An exhaust pipe 222 is connected to a side surface of the exhaust chamber 221. An exhaust device 223 including a vacuum pump, a pressure control valve, and the like is connected to the exhaust pipe 222. In addition, the interior of the processing container 201 may be brought into a vacuum state by operating the exhaust device 223.

A loading/unloading port 251 is provided on a sidewall of the processing container 201 for loading and unloading the substrate W between the processing container 201 and a vacuum transfer chamber (not illustrated). The loading/unloading port 251 is configured to be opened and closed by a gate valve 252.

The gas supply mechanism 230 includes a first gas source 231, a second gas source 232, and inert gas sources 233 and 234. The first gas source 231 is connected to a pipe 236, and in turn, the pipe 236 is connected to the first gas inlet 211a. The second gas source 232 is connected to a pipe 238, and in turn, the pipe 238 is connected to the second gas inlet 211b. The inert gas source 233 is connected to a pipe 240, and in turn, the pipe 240 is connected to the pipe 236. The inert gas source 234 is connected to a pipe 242, and in turn, the pipe 242 is connected to the pipe 238.

The film formation gas is supplied from the first gas source 231, and the etching gas is supplied from the second gas source 232. When film formation requires a reactive gas, the reactive gas may be used as the etching gas and is supplied from the second gas source 232. The inert gas such as a N₂ gas or an Ar gas is supplied from the inert gas sources 233 and 234. The inert gas is used as a carrier gas, a purge gas, or a diluent gas.

The film formation gas is supplied from the first gas source 231 and the etching gas (or the reactive gas as the etching gas) is supplied from the second gas source 232, so that a film may be formed by CVD or ALD simultaneously with etching. In addition, the reactive gas may be used separately from the etching gas, and a plurality of gases may be used as the film formation gas, the etching gas, or the reactive gas. In these cases, the number of gas sources and pipes may be increased depending on the types of gases.

The pipe 236 is provided with an on-off valve 236a, and a flow rate controller 236b such as a mass flow controller on the upstream side of the on-off valve 236a. Further, the pipes 238, 240 and 242 are similarly provided with on-off valves 238a, 240a and 242a, and flow rate controllers 238b, 240b and 242b, respectively.

The gas to be supplied may be plasmarized during film formation. In that case, for example, a radio-frequency power supply is connected to the shower head 210 and the susceptor 202 is grounded so that a radio frequency electric field is created between the shower head 210 and the susceptor 202 to plasmarize the gas.

The substrate processing apparatus 200 includes a controller 260. The controller 260 controls each component of the substrate processing apparatus 200 such as a valve, a flow rate controller, various driving mechanisms, and the heater power supply 206. The controller 260 includes a main controller equipped with a CPU, an input device, an output device, a display device, and a storage device. A storage medium that stores a program, that is, a processing recipe for controlling a processing executed in the substrate processing apparatus 200, is set in the storage device. The main controller calls a predetermined processing recipe stored in the storage medium, and controls the substrate processing apparatus 200 to execute a predetermined processing based on the processing recipe.

In the substrate processing apparatus 200 configured as described above, the controller 260 performs a processing as follows based on the processing recipe stored in the storage medium.

First, the gate valve 252 is opened, and the substrate W is loaded into the processing container 201 through the loading/unloading port 251 by a transfer device (not illustrated) and is placed on the susceptor 202. Then, after closing the gate valve 252, while the interior of the processing container 201 is exhausted by the exhaust device 223 to adjust the internal pressure of the processing container 201, the inert gas such as a N₂ gas is supplied, and a temperature of the substrate W is raised to a predetermined temperature by the heater 205.

Subsequently, while continuing to supply the inert gas, the film formation gas and the etching gas (or the reactive gas as the etching gas) are supplied into the processing container 201. Thus, the second film 5 serving as the cap layer may be formed as illustrated in FIG. 3 or 4 while etching the first film 3 of FIG. 2, which may result in the formation of the air gap 6.

After the above processing is completed, the interior of the processing container 201 is purged with the inert gas, the gate valve 252 is opened, and the substrate W is unloaded through the loading/unloading port 251 by the transfer device (not illustrated).

### SPECIFIC EXAMPLES

Next, specific examples will be described.

In a first example, the insulation film 2 of FIG. 2 is a SiO₂ film, the first film 3 embedded in the trench is an amorphous Si (a-Si) film, a butadiene (C₄H₆) gas is used as the film formation gas, and a Cl₂ gas is used as the etching gas. The Cl₂ gas is a gas that lowers a film formation temperature and also contributes to film formation. The second film 5 is formed of an a-C film serving as the cap layer by thermal CVD using a mixed gas of the C₄H₆ gas and the Cl₂ gas, and the a-Si film is removed by etching with the Cl₂ gas, resulting in an air gap formed in a portion where the a-Si film was present. Representative process conditions in a case of using the batch-type vertical furnace illustrated in FIGS. 5 and 6 as the film forming apparatus are as follows.
Processing temperature (substrate temperature): 350 degrees C. to 400 degrees C.
Flow rate of Cl₂ gas: 0.1 slm to 0.5 slm
Flow rate of C₄H₆ gas: 0.5 slm to 1.0 slm
Pressure: 0.5 Torr to 4.5 Torr
Processing time: 1 hour to 5 hours.

By adjusting these processing conditions, it is possible to adjust a film thickness of the a-C film serving as the cap layer while adjusting a removal amount of the a-Si film. The removal amount and the film thickness at this time may be effectively adjusted by adjusting an additive concentration of the Cl₂ gas or a deposition rate of the a-C film.

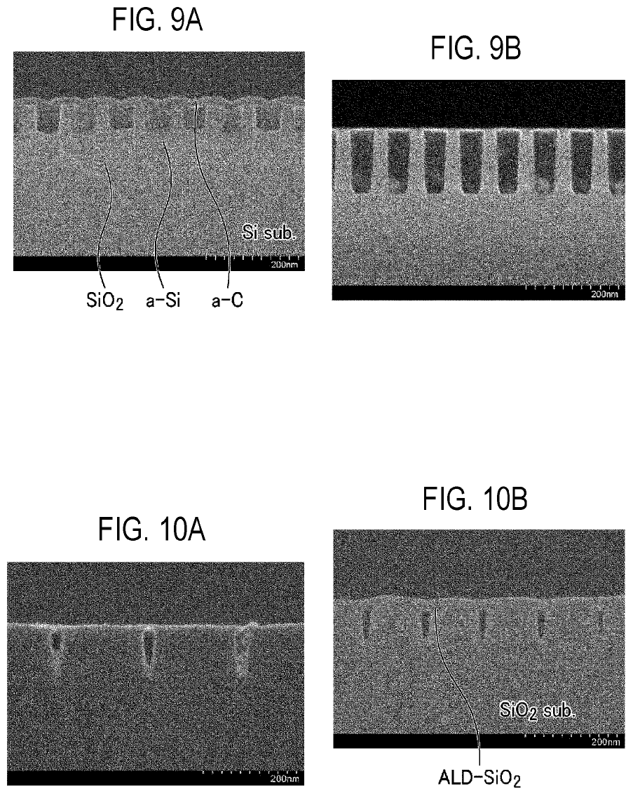

In practice, the a-C film serving as the cap layer was formed while removing the a-Si film by adjusting the above processing conditions. FIGS. 9A and 9B are SEM photographs at that time. FIG. 9A illustrates a state where the a-Si film is removed halfway by etching, and FIG. 9B illustrates a state where the a-Si film is almost completely removed by etching. It can be seen that, in both the states, an air gap is formed in a portion where the a-C film is formed as the cap layer and the a-Si film is removed.

In a second example, the insulation film 2 of FIG. 2 is a SiO₂ film, and the first film 3 embedded in the trench is a Ru film. That is, a pattern in which the Ru film is embedded in the trench of the SiO₂ film is formed. A diisophyllaminosilane (DIPAS) gas, which is an aminosilane gas, is used as the film formation gas, and an O₃ gas), which is an oxidizing agent, is used as the reactive gas. The O₃ gas) also functions as the etching gas. The second film 5 made of SiO₂ is formed by ALD in which the DIPAS gas and the O₃ gas) are alternately supplied while performing purging with an inert gas between the supply of the DIPAS gas and the supply of the O₃ gas), and the Ru film is removed by etching with the O₃ gas). Representative process conditions in a case of using the batch-type vertical furnace illustrated in FIGS. 5 and 6 as the film forming apparatus are as follows.
Processing temperature (substrate temperature): 200 degrees C. to 300 degrees C.
Aminosilane gas (DIPAS gas): 150 sccm to 300 sccm
Pressure: 1 Torr to 5 Torr
Time (per time): 2 sec to 30 sec
Flow rate (concentration) of O₃ gas): 6.5 slm to 10 slm (200 g/m³ to 250 g/m³)
Pressure: 0.5 Torr to 1 Torr
Time (per time): 10 sec to 600 sec

By adjusting these processing conditions, it is possible to adjust the film thickness of the SiO₂ film serving as the cap layer while adjusting the removal amount of the Ru film.

In practice, a cap film was formed of the SiO₂ film while removing the Ru film by adjusting the above processing conditions. FIGS. 10A and 10B are SEM photographs at that time. FIG. 10A illustrates a state where the SiO₂ film serving as the cap layer is thin, and FIG. 9B illustrates a state where the SiO₂ film serving as the cap layer is thick and the a-Si film is almost completely removed by etching. It can be seen that, in both the states, an air gap is formed in a portion where the Ru film was removed by etching.

### Second Embodiment

Next, a second embodiment will be described.

A substrate processing method of the present embodiment uses the method of the first embodiment in which a new film is formed while removing another film by etching to form a fine pattern.

In recent years, a self-aligned double patterning technique, which is called double patterning or quadruple patterning in which double patterning is performed twice, is put into practical use to form a fine circuit. By this technique, miniaturization of circuit dimensions exceeding the limit of an optical lithography device becomes possible.

Side-wall image transfer (SWT) is used as a representative example of the self-aligned double patterning technique. In SWT in the related art, it was necessary to conformally deposit a double patterning material to form a side-wall after patterning a core material. However, in this case, there are numerous problems such as very cumbersome processes, a deterioration in the roughness of a pattern caused by finely finishing the line width, and tracing to a transferred pattern.

In the substrate processing method of the present embodiment, the core material and the first film serving as an embedding material are formed in the trench of the insulation film to have a stable physical film thickness, and removal of the embedding material and formation of a new sidewall film are performed from above. Thus, the problems such as very cumbersome steps and a deterioration in the roughness of the pattern caused by finely finishing the line width may be solved, and side-wall patterning using an ultra-fine core material, which is originally impossible to stand on its own, becomes possible.

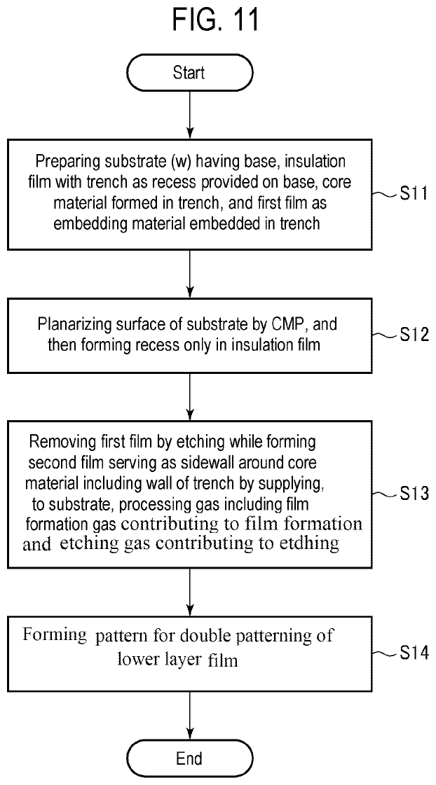

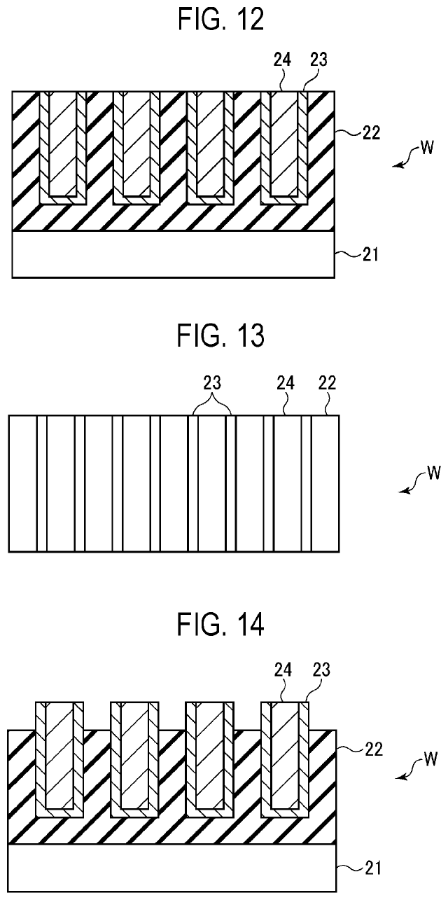

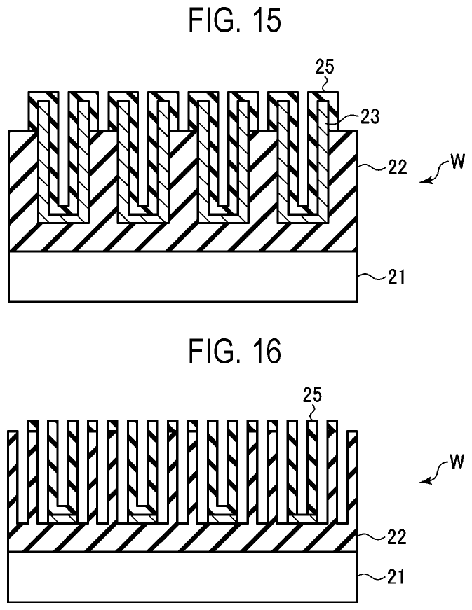

Next, a substrate processing method according to a second embodiment will be described in detail. FIG. 11 is a flowchart illustrating a pattern forming method including the substrate processing method according to the second embodiment, FIG. 12 is a cross-sectional view illustrating a substrate to which the pattern forming method is applied, FIG. 13 is a plan view illustrating the substrate to which the pattern forming method is applied, FIG. 14 is a cross-sectional view illustrating a state of the substrate on which the substrate processing method according to the second embodiment is performed, FIG. 15 is a cross-sectional view illustrating a state of the substrate after performing the substrate processing method according to the second embodiment, and FIG. 16 is a cross-sectional view illustrating a state where a pattern was formed on the substrate of FIG. 15.

In the pattern forming method, first, as illustrated in FIG. 12 (cross-sectional view) and FIG. 13 (plan view), the substrate W, which includes a base 21, an insulation film 22 having a trench as a recess formed on the base 21, a core material 23 formed in the trench, and a first film 24 as an embedding material filling the trench, is prepared (step S11).

Subsequently, as illustrated in FIG. 14, after planarizing a surface of the substrate W by CMP, only the insulation film 22 is recessed (step S12).

Subsequently, a processing gas including a film formation gas contributing to film formation and an etching gas contributing to etching is supplied to the substrate W. As illustrated in FIG. 15, a second film 25 serving as a sidewall is formed around the core material 23 including a wall of the trench while removing the first film 24 by etching (step S13).

After performing the substrate processing method of the present embodiment as described above, a pattern for double patterning of a lower layer film is formed in a state of FIG. 16 (step S14). This step is performed by etching back the second film 25 to expose the core material 23, and then etching the core material 23 and the insulation film 22 using the second film 25, which serves as the sidewall, as a mask.

The substrate W is not particularly limited, but a semiconductor wafer in which the base 21 includes a semiconductor base is exemplified. The base 21 may be a semiconductor base having one layer or a plurality of layers stacked thereon. The insulation film 22 is, for example, an interlayer insulation film. Examples of the insulation film 22 may include a SiO₂ film, a SiN film, a SiOC film, a SiOCN film, a SiCN film, a SiBN film, and a SiBCN film. The core material 23 is made of a material that is not etched during film formation in step S13, such as tantalum (Ta), tantalum nitride (TaN), titanium (Ti), and titanium nitride (TiN). The first film 24 is a film to be removed by the etching gas during film formation in step S13, and is appropriately selected depending on the combination with the used etching gas, as in the first embodiment.

The processing gas used in step S13 is the same as the processing gas used in step S2 of the first embodiment. That is, the processing gas may include an inert gas, in addition to the film formation gas and the etching gas. Further, the film formation gas may be one that forms a film by thermal decomposition, or may be one that forms a film by reacting with a reactive gas. When using the reactive gas, the reactive gas may be used as the etching gas.

The etching gas (reactive gas) may be a halogen-containing gas (for example, a Cl₂ gas, a BCl₃ gas, a F₂ gas, a HF gas, a HI gas, a HBr gas, a CH₃I gas, and a C₂H₅I gas), an oxidizing gas (for example, an O₂ gas, an O₃ gas), an O₂ Plasma, a H₂O gas, and a H₂O₂ gas), a nitriding gas (H₂/NH₃ plasma, and a hydrazine compound), and the like, as in the first embodiment. The first film 24 to be removed by etching may be made of the same material as the first film 3 of the first embodiment. That is, when the etching gas is a halogen-containing gas, Si, Ge, W, B, Al, or the like may be used as the first film 24. When the etching gas is an oxidizing gas, Ru, C (organic film), or the like may be used as the first film 24. When the etching gas is a nitriding gas such as H₂/NH₃ plasma, an organic film may be used as the first film 24 to be removed by etching.

The film formation gas is not particularly limited as long as it may form the second film 25 serving as the sidewall, but a carbon compound gas such as a hydrocarbon gas, or silicon compound gas such as a silane-based gas, a chlorosilane-based gas, or an aminosilane-based gas may be suitably used as the film formation gas, as in the case of forming the cap film 5 according to the first embodiment. A C film is formed by using the carbon compound gas, and a Si-based film such as SiO₂ or SiN is formed by using the silicon compound gas.

The film forming method of forming the second film 25 serving as the sidewall may be the same as the film forming method of forming the second film 5 according to the first embodiment. That is, the film forming method may be CVD, or may be ALD when the reactive gas is used, and plasma may be used during film formation.

In step S13, the second film 25 may be formed on the wall of the trench after the first film 24 is removed by giving etching superiority over film formation. By making the ratio of the etching gas higher than that of the film formation gas, etching may attain superiority. Further, etching may attain superiority by including a period in which only the etching gas is supplied. For example, etching may attain superiority by initially supplying the etching gas to precede etching and then supplying the film formation gas and the etching gas.

In step S13, materials of the film to be removed and the film to be formed, the combination of a film formation raw material and the etching gas (reactive gas), and the like may be the same as those in step S2 of the first embodiment.

Also in step S13 of the present embodiment, the removal of the first film 24 by etching and the formation of the second film 25 may be appropriately performed by adjusting processing conditions such as a gas supply timing, processing temperature, gas flow rate, and gas ratio.

The substrate processing apparatus for performing step S13 may be a batch-type vertical furnace illustrated in FIGS. 5 to 7 or a single-wafer-type vertical furnace illustrated in FIG. 8, as in the first embodiment.

Examples of the core material 23, the first film 24, the second film 25, the gas to be used, and the film forming method are as follows.
Core material 23: Ta
First film 24: Ru
Second film 25: SiO₂ film
Film formation gas: silicon compound gas (silane-based gas, chlorosilane-based gas, aminosilane-based gas)
Etching gas (reactive gas): oxidizing gas (O₂ gas, O₃ gas))
Film forming method: ALD

### OTHER APPLICATIONS

Although the embodiments have been described above, the embodiments disclosed herein should be considered to be exemplary and not restrictive in all respects. The above embodiments may be omitted, replaced or modified in various forms without departing from the scope of the appended claims and their gist.

For example, a configuration of the substrate in the above embodiment is illustrative, and is not restrictive. Further, although a batch-type vertical furnace and a single-wafer-type apparatus are illustrated as the film forming apparatus, they are examples, and various apparatuses having other configurations may be used.

### EXPLANATION OF REFERENCE NUMERALS

1, 21: base, 2, 22: insulation film, 3: first film, 4: structure, 5: second film, 6: air gap, 23: core material, 24: first film, 25: second film (sidewall), 100, 200: substrate processing apparatus, 101, 201: processing container, 102: main body, 120, 230: gas supply mechanism, 151, 223: exhaust device, 152: heating mechanism, 160, 260: controller, 205: heater, W: substrate

1-19. (canceled)

20. A substrate processing method comprising:
preparing a substrate having a recess and a first film embedded in the recess; and
removing the first film by etching while forming a second film so as to cover the recess from which the first film was removed by supplying a processing gas to the substrate, the processing gas including a gas contributing to film formation and a gas contributing to the etching.

21. The substrate processing method of claim 20, wherein an air gap is formed in the recess covered with the second film.

22. The substrate processing method of claim 20, wherein the removing the first film by the etching and the forming the second film are performed simultaneously.

23. The substrate processing method of claim 20, wherein the second film is formed so as to cover the recess from which the first film was removed by giving the film formation superiority over the etching.

24. The substrate processing method of claim 20, wherein the first film is partially or wholly removed by the etching.

25. The substrate processing method of claim 20, wherein the gas contributing to the film formation is a hydrocarbon gas, and the gas contributing to the etching is a halogen-containing gas.

26. A substrate processing method comprising:
preparing a substrate having a recess and a first film embedded in the recess; and
removing the first film by etching while forming a second film on a portion including a wall of the recess from which the first film was removed by supplying a processing gas to the substrate, the processing gas including a gas contributing to film formation and a gas contributing to the etching.

27. The substrate processing method of claim 26, wherein the second film is formed on the wall of the recess by giving the etching superiority over the film formation.

28. The substrate processing method of claim 27, wherein the etching attains superiority over the film formation by making a ratio of the gas contributing to the etching higher than a ratio of the gas contributing to the film formation.

29. The substrate processing method of claim 27, wherein a period in which only the gas contributing to the etching is supplied is set so that the etching attains superiority over the film formation.

30. The substrate processing method of claim 26, wherein the recess has a core material formed on an inner wall of the recess with the first film being embedded in a remaining portion and an upper portion of the substrate is recessed so that the core material and the first film are in an exposed state, and by supplying the processing gas including the gas contributing to the film formation and the gas contributing to the etching, to the substrate in the exposed state, the second film is formed as a sidewall on both sides of a portion where the core material is exposed.

31. The substrate processing method of claim 26, wherein the gas contributing to the film formation is a hydrocarbon gas, and the gas contributing to the etching is a halogen-containing gas.

32. The substrate processing method of claim 31, wherein the first film is selected from among silicon, germanium, tungsten, boron, and aluminum, and the second film is amorphous carbon formed by thermal CVD.

33. The substrate processing method of claim 26, wherein the gas contributing to the film formation is a silicon compound gas, and the gas contributing to the etching is an oxidizing gas as a reactive gas that reacts with the silicon compound gas.

34. The substrate processing method of claim 33, wherein the silicon compound gas is an aminosilane-based gas, and the oxidizing gas is an O₂ gas or an O₃ gas).

35. The substrate processing method of claim 33, wherein the first film is ruthenium or carbon, and the second film is a SiO₂ film formed by CVD or ALD.

36. The substrate processing method of claim 26, wherein the gas contributing to the film formation is a silicon compound gas, and the gas contributing to the etching is a nitriding gas as a reactive gas that reacts with the silicon compound gas.

37. The substrate processing method of claim 36, wherein the nitriding gas is plasma of a H₂ gas and a N₂ gas.

38. The substrate processing method of claim 36, wherein the first film is an organic film, and the second film is a SiN film formed by CVD or ALD.

39. A substrate processing apparatus comprising:
a processing container in which a substrate having a recess and a first film embedded in the recess is accommodated;
a gas supply mechanism configured to supply a processing gas into the processing container, the processing gas including a gas contributing to film formation and a gas contributing to etching;
a heater configured to heat the substrate inside the processing container; and
a controller configured to control the gas supply mechanism and the heater,
wherein the controller controls the gas supply mechanism to supply, to the substrate, the processing gas including the gas contributing to the film formation and the gas contributing to the etching so that the first film is removed by the etching and a second film is formed to cover the recess from which the first film was removed, or on a portion including a wall of the recess from which the first film was removed.
